(19) United States
(12) Patent Application Publication
(10) Pub. No.: US 2010/0032012 A1
(43) Pub. Date: Feb. 11, 2010

(54) SOLAR CELL AND METHOD OF MANUFACTURING THE SAME

(76) Inventors: Takayuki Isaka, Osaka (JP); Yasushi Funakoshi, Osaka (JP); Masatsugu Kohira, Osaka (JP)

Correspondence Address: NIXON & VANDERHYE, PC, 901 NORTH GLEBE ROAD, 11TH FLOOR, ARLINGTON, VA, 22203, US

(21) Appl. No.: 12/517,008

(22) PCT Filed: Nov. 19, 2007
(86) PCT No.: PCT/JP2007/072343

§ 371 Date: May 29, 2009

(30) Foreign Application Priority Data
Dec. 1, 2006 (JP) 2006-325760

(51) Int. Cl. H01L 31/0216

(52) U.S. Cl. 136/256; 438/57; 257/E31.119

(57) ABSTRACT

A solar cell (10) including a passivation film having a high effect for both a p region and an n region on a surface of a silicon substrate of the solar cell is provided. In the solar cell, a first passivation film made of a silicon nitride film is formed on a surface opposite to a light-receiving surface of the silicon substrate, and the first passivation film has a refractive index of not less than 2.6. Preferably, in the solar cell, a second passivation film including a silicon oxide film and/or an aluminum oxide film is formed between the silicon substrate and the first passivation film. Preferably, the solar cell is a back surface junction solar cell having a pn junction formed on the surface opposite to the light-receiving surface of the silicon substrate.

### TECHNICAL FIELD

The present invention relates to a solar cell and a method of manufacturing the same. More specifically, The present invention relates to a solar cell using a passivation film with a high refractive index on a surface opposite to a light-receiving surface of a silicon substrate, and a method of manufacturing the same.

### BACKGROUND ART

Conventional solar cells generally employ a structure in which a pn junction is formed in the vicinity of a light-receiving surface by diffusing impurities having a conductivity type opposite to a conductivity type of a substrate into the light-receiving surface, and one electrode is disposed on the light-receiving surface and. the other electrode is disposed on a surface opposite to the light-receiving surface. It is also common to heavily diffuse impurities having a conductivity type identical to the conductivity type of the substrate into the opposite surface to achieve high output by a back surface field effect.

On the other hand, in a solar cell having such a structure, the electrode formed on the light-receiving surface blocks incident light, suppressing the output of the solar cell. Accordingly, to solve the problem, so-called back surface junction solar cells having both an electrode of one conductivity type and an electrode of the other conductivity type (that is, a p electrode and an n electrode) on a back surface have been developed in recent years.

Since such a back surface junction solar cell has a pn junction on a back surface, it is important for efficient collection of minority carriers to increase the life of minority carriers in a substrate bulk layer and to suppress recombination of minority carriers on a substrate surface. That is, to obtain an excellent photoelectric conversion efficiency in the solar cell of this type, it is necessary to increase the life of minority carriers generated in a substrate by receiving light.

A method of forming a passivation film is used as a method of suppressing recombination of minority carriers on a substrate surface. However, since a p region and an n region are formed on an identical surface in a back surface junction solar cell, there is a strong demand for developing a passivation film that is effective for both the p region and the n region.

Further, Patent Document 1 (Japanese Patent Laying-Open No. 10-229211) discloses a technique in which a passivation film formed on a silicon substrate is made of silicon nitride. It also discloses a technique of forming the passivation film to have a multi-layered structure and thereby effectively exhibiting a passivation effect caused by fixed charges at an interface between the passivation film and an exposed end surface of the silicon substrate.

### Patent Document 1: Japanese Patent Laying-Open No. 10-229211

### DISCLOSURE OF THE INVENTION

### Problems to be Solved by the Invention

Generally, a silicon oxide film is used as a passivation film on a back surface of a silicon substrate of a solar cell. A. silicon oxide film, in particular a silicon oxide film formed by a thermal oxidation method (hereinafter also referred to as a thermally oxidized film), has a high passivation effect, and is widely used as a passivation film for solar cells. However, since the film forming speed of the thermally oxidized film varies depending on the concentration of impurities in the silicon substrate, the thermally oxidized film is likely to have an uneven film thickness depending on the state of the silicon substrate.

On the other hand, in a case where a silicon nitride film is formed as a passivation film on a back surface of a silicon substrate of a solar cell, a relatively high passivation effect can be obtained, although not to the extent of the passivation effect obtained by the thermally oxidized film. Further, unlike the thermally oxidized film, the silicon nitride film can be formed to have an even film thickness regardless of the state of the silicon substrate. Furthermore, the silicon nitride film is highly resistant to hydrogen fluoride used during a process of manufacturing solar cells.

However, since the silicon nitride film has positive fixed charges, the silicon nitride film is considered to be inappropriate as a passivation film for a p region of a solar cell.

In view of the above-mentioned problems, one object of the present invention is to provide a solar cell including a passivation film having a high effect for both a p region and an n region on a surface of a silicon substrate of a solar cell.

### Means for Solving the Problems

The present invention relates to a solar cell including a first passivation film made of a silicon nitride film formed on a surface opposite to a light-receiving surface of a silicon substrate, the first passivation film having a refractive index of not less than 2.6.

Preferably, the solar cell of the present invention is a back surface junction solar cell having a pn junction formed on the surface opposite to the light-receiving surface of the silicon substrate.

Preferably, in the solar cell of the present invention, a second passivation film including a silicon oxide film and/or an aluminum oxide film is formed between the silicon substrate and the first passivation film.

Further, the present invention relates to a manufacturing method of a solar cell including a first passivation film made of a silicon nitride film formed on a surface opposite to a light-receiving surface of a silicon substrate, the first passivation film having a refractive index of not less than 2.6.

Preferably, the manufacturing method of the present invention includes the step of forming the first passivation film by a plasma CVD method using a mixed gas containing a first gas and a second gas, a mixing ratio of the second gas to the first gas in the mixed gas being not more than 1.4, the mixed gas containing nitrogen, the first gas including silane gas, and the second gas including ammonia gas.

Preferably, the manufacturing method of the present invention includes the step of forming a pn junction on the surface opposite to the light-receiving surface of the silicon substrate.

Preferably, the manufacturing method of the present invention includes the step of forming a second passivation film including a silicon oxide film between the silicon substrate and the first passivation film, and the silicon oxide film is formed by a thermal oxidation method.

Preferably, the manufacturing method of the present invention includes the step of performing annealing treatment on the silicon substrate after the step of forming the first passivation film.

Preferably, in the manufacturing method of the present invention, the step of performing annealing treatment is performed in an atmosphere containing hydrogen and an inert gas.

Preferably, in the manufacturing method of the present invention, the step of performing annealing treatment is performed in an. atmosphere containing 0.1 to 4.0% of hydrogen.

Preferably, in the manufacturing method of the present invention, the step of performing annealing treatment is performed at 350 to 600° C. for five minutes to one hour.

### EFFECTS OF THE INVENTION

According to the present invention, a solar cell including a passivation film having a high passivation effect for both a p region and an n region on a surface of a silicon substrate of a solar cell can be obtained.

### BRIEF DESCRIPTION OF THE DRAWINGS

FIG. 1 is a front view of one preferred mode of a solar cell of the present invention, as seen from a side on which sunlight is not incident.

FIG. 2 is a cross sectional view taken along the line I-II of FIG. 1.

FIG. 3(a) shows the relationship between the refractive index of a silicon nitride film formed on an n-type silicon substrate and the lifetime of minority carriers in the silicon substrate, and FIG. 3(b) shows the relationship between the refractive index of a silicon nitride film formed, on an n-type silicon substrate having a p region formed on a surface thereof and the lifetime of rminority carriers in the silicon substrate.

FIG. 4 shows the relationship between the mixing ratio of a second gas to a first gas when a silicon nitride film is formed by a plasma CVD method using a mixed gas containing the first gas and the second gas and the refractive index of the formed silicon nitride film.

FIG. 5 is a cross sectional view showing steps in one mode of a method of manufacturing a solar cell of the present invention.

### DESCRIPTION OF THE REFERENCE SIGNS

1. silicon substrate, 2: antireflection film, 3: passivation film, 4: texture structure, 5: p+ layer, 6: n+ layer, 7; texture mask, 8: diffusion mask, 10: solar cell, 11: p electrode, 12: n electrode.

### BEST MODES FOR CARRYING OUT THE INVENTION

In the specification, a surface of a silicon substrate of a solar cell on which sunlight is incident is referred to as a light-receiving surface, and a surface of the silicon substrate which is opposite to the light-receiving surface and on which sunlight is not incident is referred to as an opposite surface or a back surface.

Further, hereinafter, in the drawings of the present application, identical or corresponding parts will be designated by the same reference characters. Furthermore, the dimensional relationship among lengths, sizes, widths, and the like in the drawings is changed as appropriate for clarity and simplicity of the drawings, and does not represent actual dimensions,

### <Structure of Solar Cell>

Although a solar cell of the present invention may be of any form, it is preferably a back surface junction solar cell having a pn junction formed on a surface opposite to a light-receiving surface of a silicon substrate. Accordingly, a solar cell of the present invention will be described below, taking a back surface junction solar cell as an example.

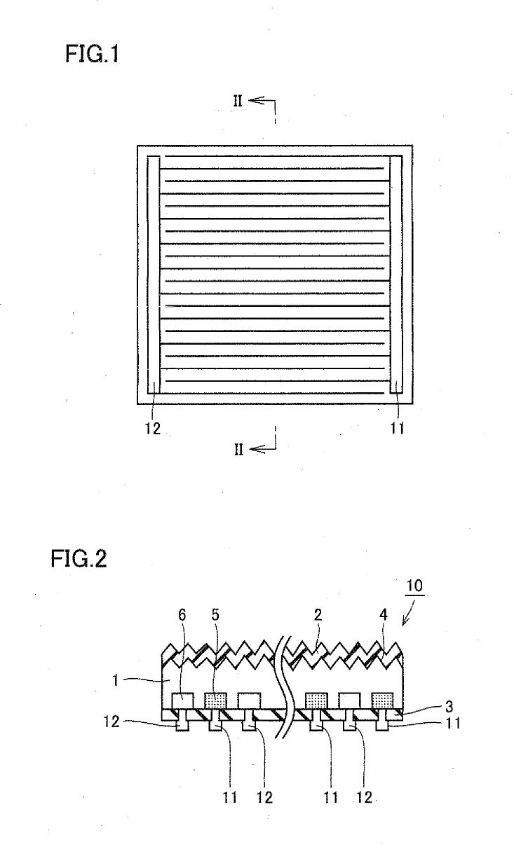

FIG. 1 is a front view of one preferred mode of a solar cell of the present invention, as seen from a side on which sunlight is not incident. FIG. 2 is a cross sectional view taken along the line II-II of FIG. 1.

A solar cell 10 of one preferred mode of the present invention is a back surface junction solar cell, and uses a silicon substrate 1 as a material as shown in FIG. 2. A plurality of p+ layers 5 and a plurality of n+ layers 6 are alternately formed and spaced apart on a back surface of silicon substrate 1. A p electrode 11 and an n electrode 12 are formed on each p+ layer 5 and each n+ layer 6, respectively. Further, the back surface of silicon substrate 1 other than places where p electrode 11 and n electrode 12 are formed is covered with a passivation film 3. In the present invention, passivation film 3 includes both the one formed of a first passivation film only, and the one formed of a laminated body having a first passivation film and a second passivation film (not shown). Further, a texture structure 4 is formed on a light-receiving surface of silicon substrate 1, and covered with an antireflection film 2. Preferably, as shown in FIG. 1, p electrode 11 and n electrode 12 are formed to have a comb-like shape so as not to overlap each other. It is to be noted that passivation film 3 is not necessarily required to be formed on the entire back surface of silicon substrate 1:

As shown in FIG. 2, passivation film 3 is formed on the back surface of silicon substrate 1. In the present invention, the structural pattern of passivation film 3 is one of the following two patterns:
(1) As passivation film 3, only the first passivation film is directly formed on the back surface of silicon substrate 1;
(2) As passivation film 3, the second passivation film is formed on the back surface of silicon substrate 1 and the first passivation film is formed thereon.

In the case of (2) described above, in short, the second passivation film is formed between the back surface of silicon substrate 1 and the first passivation film. In this case, the second passivation film is not required to be formed on the entire back surface of silicon substrate 1, and may be formed sparsely. Preferably, passivation film 3 of the present invention has a thickness of 5 to 200 nm. If passivation film 3 has a thickness of less than 5 nm, it may not exhibit a high passivation effect. If passivation film 3 has a thickness of more than 200 nm, etching for forming an arbitrary pattern in passivation film 3 during the manufacturing process may be incomplete.

### <Passivation Film>

The first passivation film of the present invention is made of a silicon nitride film, and has a refractive index of not less than 2.6, more preferably not less than 2.8. The second passivation film includes a silicon oxide film and/or an aluminum oxide film. The second passivation film may be a laminated body having a silicon oxide film and an aluminum oxide film, may be formed of an aluminum oxide film only, or may be formed of a silicon oxide film only. However, the second passivation film formed of a silicon oxide film only is particularly preferable.

### <<First Passivation Film>>

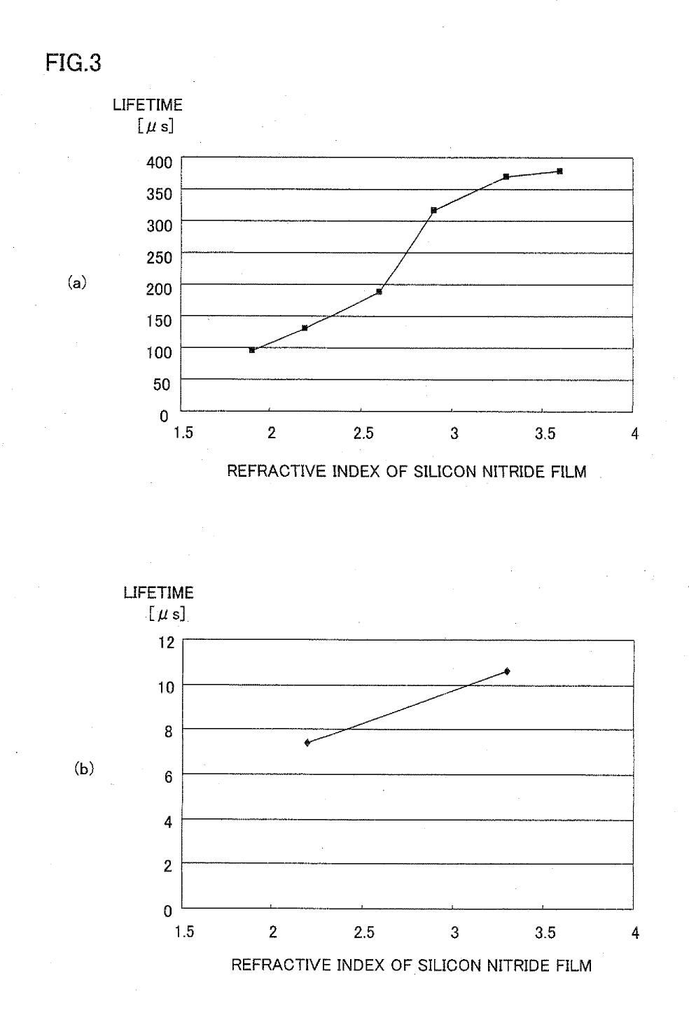

FIG. 3(a) shows the relationship between the refractive index of a silicon nitride film formed on an n-type silicon substrate and the lifetime of minority carriers in the silicon substrate, and FIG. 3(b) shows the relationship between the refractive index of a silicon nitride film formed on an n-type silicon substrate having a p region formed on a surface thereof and the lifetime of minority carriers in the silicon substrate. In FIGS. 3(a) and 3(b), the axis of abscissas represents a value of the refractive index of the silicon nitride film, and the axis of ordinates represents the lifetime of minority carriers in the silicon substrate (unit: microseconds). It is to be noted that a silicon nitride film used as a passivation film for a semiconductor such as a silicon substrate generally has a refractive index of about 2.

As shown in FIG. 3(a), the n-type silicon substrate having a silicon nitride film with a refractive index of about 2 formed on a surface thereof has a lifetime of minority carriers (hereinafter, a “lifetime of minority carriers” will be simply referred to as a “lifetime”) of about 100 μs. However, the silicon substrate having a silicon nitride film with a refractive index of 2.6 formed on a surface thereof has a lifetime of about 190 μs. Further, the silicon substrate having a silicon nitride film with a refractive index of not less than 2.6 formed on a surface thereof has a lifetime with a significantly increased value, when compared with the silicon substrate having a silicon nitride film with a refractive index of 2 formed on a surface thereof. That is, there is shown a tendency that recombination of minority carriers can further be prevented if a silicon nitride film formed on the silicon substrate has a higher refractive index. Therefore, preferably, the first passivation film of the present invention has a refractive index of not less than 2.6. This is because, the first passivation film has a refractive index of less than 2.6, the silicon substrate has a short lifetime, and thus there arises a tendency that recombination of minority carriers cannot be prevented effectively.

Further, it can be confirmed that, as shown in FIG. 3(b), the value of the lifetime is increased with an increase in the value of the refractive index of a silicon nitride film formed on an n-type silicon substrate having a p region formed on a surface thereof. Therefore, it is shown that, when a silicon nitride film is used as a passivation film for a p region in an n-type silicon substrate, it is preferable that the silicon nitride film has a high refractive index.

Generally, a silicon nitride film has a large amount of positive fixed charges, and thus the silicon nitride film is considered to be inappropriate as a passivation film for a p region in a p-type silicon substrate and a p region in an n-type or p-type silicon substrate. However, when a silicon nitride film with a refractive index of not less than 2.6 is used as the first passivation film as in the present invention, the lifetime of the silicon substrate is improved as described above, and thus it is considered that recombination of minority carriers can be prevented. This phenomenon occurs because the silicon nitride film with a refractive index of not less than 2.6 has positive fixed charges smaller than that of the silicon nitride film with a refractive index of about 2.

The solar cell of the present invention, in particular a back surface junction solar cell, having the first passivation film only as a passivation film has an open voltage slightly lower than that of a conventional solar cell using a silicon oxide film only as a passivation film. However, a short circuit current in the solar cell of the present invention is improved, when compared with that of the conventional solar cell. Consequently, the solar cell having the first passivation film only as a passivation film has improved properties, when compared with those of the conventional solar cell,

It is to be noted that the measurement of the lifetime in FIGS. 3(a) and 3(b) was performed using the reflected microwave photoconductive decay method (micro PCD method).

### <<Second Passivation Film>>

The second passivation film is formed between the first passivation film and the silicon substrate. As described above, the second passivation film includes a silicon oxide film and/or an aluminum oxide film. However, the second passivation film formed of a silicon oxide film only is particularly preferable, for the following reasons. Firstly, since a silicon oxide film, particularly a thermally oxidized film, is formed at a high temperature, the film can exhibit a satisfactory passivation effect even in a high temperature stage during the process of manufacturing solar cells without changing its properties, On the other hand, an aluminum oxide film is not suitable as a passivation film for an n region, as aluminum contained therein may be introduced as impurities into the silicon substrate and may form a p region.

Further, a silicon oxide film, particularly a thermally oxidized film, has a high passivation effect, Accordingly, a higher passivation effect can be provided by forming a thermally oxidized film as the second passivation film.

Preferably, the surface level density between the second passivation film and the p region in the solar cell of the present invention is lower than the surface level density between the first passivation film and the p region. Preferably, the silicon oxide film included in the second passivation film is formed by the thermal oxidation method.

It is to be noted that, preferably, the thickness of the second passivation film is not less than 5 nm and less than 200 nm. If the second passivation film has a thickness of less than 5 nm, it may not exhibit a high passivation effect. If the second passivation film has a thickness of not less than 200 nm, etching for forming an arbitrary pattern in the second passivation film during the manufacturing process may be incomplete.

A solar cell, in particular a back surface junction solar cell, having the second passivation film formed between the first passivation film and the silicon substrate has an improved open voltage, when compared with a solar cell having the first passivation film only as a passivation film. Therefore, the second passivation film contributes to improved properties of the solar cell, such as conversion efficiency.

### <Adjustment of Refractive Index of the First Passivation Film>

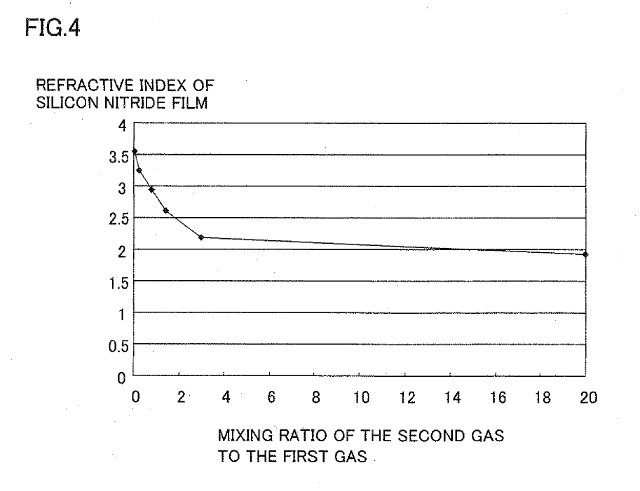

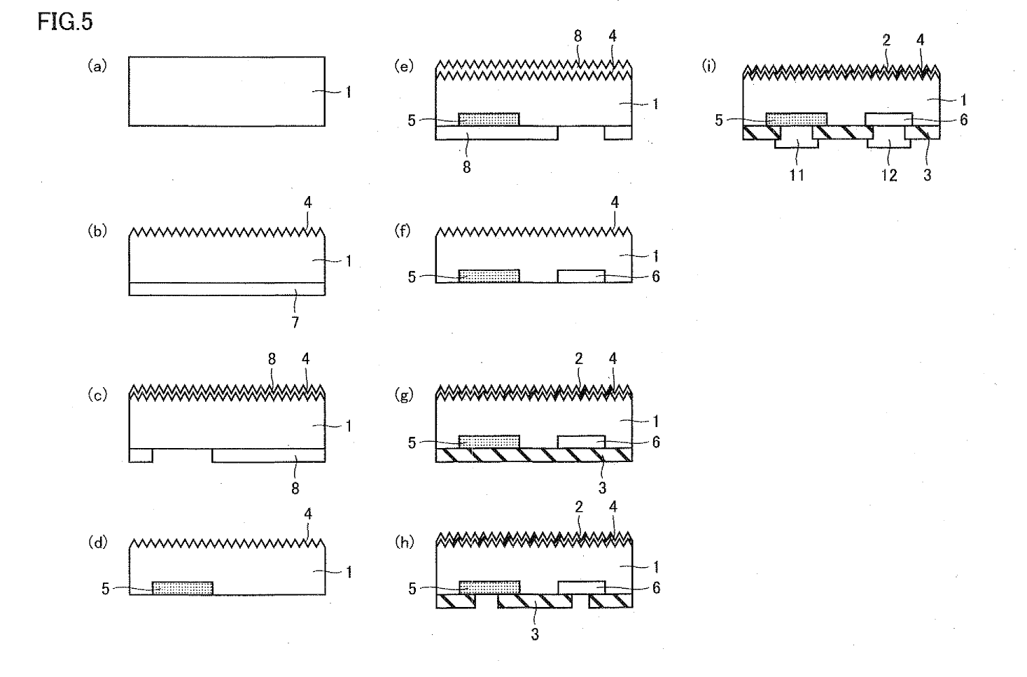

FIG. 4 shows the relationship between the mixing ratio of a second gas to a first gas when a silicon nitride film is formed on a silicon substrate by a plasma CVD method using a mixed gas containing the first gas and the second gas and the refractive index of the formed silicon nitride film. The axis of ordinates represents the refractive index of the formed silicon nitride film, and the axis of abscissas represents the mixing ratio of the second gas to the first gas.

In the present invention, the first gas includes silane gas, and the second gas includes ammonia gas. Silane gas includes, for example, SiH₄ gas, SiHCl₃ gas, SiH₂Cl₂ gas, SiH₃Cl gas, or the like, The mixed gas contains nitrogen, in addition to the first gas and the second gas.

As shown in FIG. 4, there has been shown a tendency that the refractive index of the formed silicon nitride film is decreased with an increase in the mixing ratio of the second gas to the first gas. On that occasion, the proportion of the quantity of nitrogen in the mixed gas was constant. The first passivation film with a refractive index of not less than 2.6 can be formed on the back surface of the silicon substrate by changing the mixing ratio of the second gas to the first gas in the mixed gas used for the plasma CVD method. To form the first passivation film with a refractive index of not less than 2.6, the mixing ratio of the second gas to the first gas is preferably not more than 1.4, as there is a tendency that the first passivation film with a refractive index of not less than 2.6 cannot be formed if the mixing ratio of the second gas to the first gas is more than 1.4. It is to be noted that processing by the plasma CVD method is preferably performed at a temperature of 300 to 500° C.

Further, the refractive index of FIG. 4 was measured by the ellipsometry method.

### <Method of Manufacturing Solar Cell>

FIG. 5 is a cross sectional view showing steps in one mode of a method of manufacturing a solar cell of the present invention. Although only one n+ layer and one p+ layer are formed on the back surface of the silicon substrate in FIG. 5 for convenience of description, a plurality of n+ layers and a plurality of p+ layers are actually formed. S1 (step 1) to S7 (step 7) corresponding to FIGS. 5(a) to 5(g), respectively, and S9 (step 9) and S10 (step 10) corresponding to FIGS. 5(h) and 5(i), respectively, will be each described. S8 (step 8) will be described with reference to FIG. 5(g). It is particularly necessary for the method of manufacturing a solar cell of the present invention to include “S7: Formation of Passivation Film and Antireflection Film”. The method of manufacturing a solar cell of the present invention includes, in S7, the step of forming, the second passivation film and the step of forming the first passivation film. Further, the manufacturing method of the present invention preferably includes S1 to S6, which are the steps of forming a pn junction on the back surface of the silicon substrate.

Hereinafter, a method of manufacturing solar cell 10 will be described with reference to FIG. 5.

<<S1: n-Type Semiconductor Substrate>>

As shown in FIG. 5(a), n-type silicon substrate 1 is prepared. As silicon substrate 1, the one with slice damage caused during slicing removed or the like is used. The removal of slice damage from silicon substrate 1 is performed by etching the surface of silicon substrate 1 using a mixed acid containing an aqueous solution of hydrogen fluoride and nitric acid, an alkaline aqueous solution such as sodium hydroxide, or the like. Although the size and the shape of silicon substrate 1 are not particularly limited, it can have the shape of, for example, a rectangle with a thickness of not less than 100 μm and not more than 300 μm, and a side length of not less than 100 mm and not more than 200 mm.

### <<S2: Formation of Texture Structure on Light-Receiving Surface>>

As shown in FIG. 5(b), a texture mask 7 made of a silicon oxide film or the like is formed on the back surface of silicon substrate 1 by an atmospheric pressure CVD method or the like, and then texture structure 4 is formed on the light-receiving surface of silicon substrate 1. Texture structure 4 on the light-receiving surface can be formed by etching silicon substrate 1 having texture mask 7 formed thereon, using an etching solution. As the etching solution, for example, a solution prepared by adding isopropyl alcohol to an alkaline aqueous solution such as sodium hydroxide or potassium hydroxide and heating the mixture to a temperature of not less than 70° C. and not more than 80° C. can be used. After texture structure 4 is formed, texture mask 7 on the back surface of silicon substrate 1 is removed using an aqueous solution of hydrogen fluoride or the like.

### <<S3; Formation of Opening in Diffusion Mask>>

As shown in FIG. 5(c), diffusion masks 8 are formed on the light-receiving surface and the back surface of silicon substrate 1, and an opening is formed in diffusion mask 8 on the back surface. Firstly, diffusion mask 8 made of a silicon oxide film is formed on each of the light-receiving surface and the back surface of silicon substrate 1, by steam oxidation, the atmospheric pressure CVD method, printing and sintering of an SOG (Spin On Glass) material, or the like. Then, an etching paste is applied on diffusion mask 8 on the back surface of silicon substrate 1, at a desired portion where an opening is to be formed in diffision mask 8. Subsequently, silicon substrate 1 is heat-treated, then cleaned to remove the remaining etching paste, and thereby an opening can be formed in diffusion mask 8. On this occasion, the opening is formed at a portion corresponding to a place where p+ layer 5 described below is to be formed. Further, the etching paste contains an etching component for etching diffusion mask 8.

<<S4: HF Cleaning after Diffusion of p-Type Impurities>>

As shown in FIG. 5(d), p-type impurities are diffused, and thereafter diffusion masks 8 formed in S3 are cleaned using an aqueous solution of hydrogen fluoride (HF) or the like, to form p+ layer 5 as a conductive impurities diffused layer. Firstly, p-type impurities as conductive impurities are diffused into an exposed back surface of silicon substrate 1, for example by vapor-phase diffusion using BBr₃. After the diffusion, diffusion masks 8 described above on the light-receiving surface and the back surface of silicon substrate 1, and BSG (Boron Silicate Glass) formed by diffusing boron are all removed using an aqueous solution of hydrogen fluoride or the like.

### <<S5: Formation of Opening in Diffusion Mask>>

As shown in FIG. 5(e), diffusion masks 8 are formed on the light-receiving surface and the back surface of silicon substrate 1, and an opening is formed in diffusion mask 8 on the back surface, Although the operation is the same as that in S3, the opening in diffusion mask 8 is formed in S5 at a portion corresponding to a place where n+ layer 6 described below is to be formed.

<<S6: HF Cleaning after Diffusion of n-Type Impurities>>

As shown in FIG. 5(f), n-type impurities are diffused, and thereafter diffusion masks 8 formed in S5 are cleaned using an aqueous solution of hydrogen fluoride or the like, to form n+ layer 6 as a conductive impurities diffused layer. Firstly, n-type impurities as conductive impurities are diffused into an exposed back surface of silicon substrate 1, for example by vapor-phase diffusion using POCl₃. After the diffusion, diffusion masks S described above on the light-receiving surface and the back surface of silicon substrate 1, and PSG (Phosphorus Silicate Glass) formed by diffusing phosphorus are all removed using an aqueous solution of hydrogen fluoride or the like.

### <<S7: Formation of Passivation Film and Antireflection Film>>

As shown in FIG. 5(g), antireflection film 2 made of a silicon nitride film is formed on the light-receiving surface of silicon substrate 1, and passivation film 3 is formed on the back surface thereof.

If passivation film 3 is formed of the first passivation film only, an operation as described below will be performed. Firstly, as the first passivation film, a silicon nitride film with a refractive index of not less than 2.6 is formed on the back surface of silicon substrate 1 by the plasma CVD method. On this occasion, the refractive index of the first passivation film is adjusted using the mixed gas described above. Next, antireflection film 2 made of a silicon nitride film with a refractive index of, for example, 1.9 to 2.1 is formed on the high-receiving surface of silicon substrate 1.

If passivation film 3 is formed of the first passivation film and the second passivation film, an operation as described below will be performed. Firstly, a silicon oxide film, or an aluminum oxide film, or a laminated body having a silicon oxide film and an aluminum oxide film is formed on the back surface of silicon substrate 1, as the second passivation film, Although the silicon oxide film can be formed by steam oxidation, the atmospheric pressure CVD method, or the like, it is preferably formed by the thermal oxidation method, and processing by the thermal oxidation method is preferably performed at a temperature of 800 to 1000° C. This is because film formation by the thermal oxidation method is simple, and can form a silicon oxide film which is dense, has good properties, and exhibits a high passivation effect, when compared with those formed by other manufacturing methods. The aluminum oxide film can be formed, for example, by an evaporation method.

As a result of the formation of the silicon oxide film on the back surface of silicon substrate 1 by the thermal oxidation method, a silicon oxide film is also formed simultaneously on the light-receiving surface of silicon substrate 1. In such a case, it is preferable to remove the entire silicon oxide film formed on the light-receiving surface using an aqueous solution of hydrogen fluoride or the like, with the silicon oxide film on the back surface of silicon substrate 1 protected. Then, on the formed second passivation film, the first passivation film made of a silicon nitride film with a refractive index of not less than 2.6 is formed by the plasma CVD method. The refractive index of the first passivation film is adjusted in a manner described above. Next, antireflection film 2 made of a silicon nitride film with a refractive index of, for example, 1.9 to 2.1 is formed on the light-receiving surface of silicon substrate 1. The silicon oxide film on the light-receiving surface may be removed after the formation of the first passivation film. Further, a film made of a chemical composition other than a silicon oxide film and an aluminum oxide film may be used as the second passivation film.

It is to be noted that, when passivation film 3 is formed of the first passivation film only, the thermal oxidation method is not used, and thus the process of removing the silicon oxide film formed on the light-receiving surface as described above is not required.

### <<S8: Step of Performing Annealing Treatment>>

In the present invention, it is preferable to perform annealing treatment on silicon substrate 1 after the formation of passivation film 3 and antireflection film 2. In the present invention, annealing treatment refers to performing heat treatment on silicon substrate 1. Preferably, as the annealing treatment, heat treatment is performed in an atmosphere containing hydrogen and an inert gas. Preferably, as the annealing treatment, heat treatment is performed on silicon substrate 1 at 350 to 600° C., more preferably at 400 to 500° C. This is because, if the annealing treatment is performed at a temperature of less than 350° C., an annealing effect may not be obtained, and if the annealing treatment is performed at a temperature of more than 600° C., passivation film 3 or antireflection film 2 on the surface may be destroyed (i.e., hydrogen in the film may be desorbed), causing a deterioration in properties. Further, the annealing treatment is preferably performed for five minutes to one hour, more preferably for 15 to 30 minutes. This is because, if the annealing treatment is performed for less than five minutes, an annealing effect may not be obtained, and if the annealing treatment is performed for more than one hour, passivation film 3 or antireflection film 2 on the surface may be destroyed (i.e., hydrogen in the film may be desorbed), causing a deterioration in properties.

Further, in the atmosphere for the annealing treatment, the content of hydrogen is preferably 0.1 to 4.0%, particularly preferably 1.0 to 3.0%. This is because, if the content of hydrogen in the atmosphere is less than 0.1%, an annealing effect may not be obtained, and if the content of hydrogen in the atmosphere is more than 4.0%, there is a possibility that hydrogen may explode. Furthermore, a component other than hydrogen in the atmosphere for the annealing treatment is preferably an inert gas, and specifically at least one selected from nitrogen, helium, neon, and argon. By performing the annealing treatment, properties of a formed solar cell are further improved.

### <<S9: Formation of Contact Holes>>

As shown in FIG. 5(h), to partially expose p+ layer 5 and n+ layer 6, passivation film 3 on the back surface of silicon substrate 1 is partially removed by etching, and contact holes are formed. The contact holes can be formed, for example, using the etching paste described above.

### <<S10: Formation of Electrodes>>

As shown in FIG. 5(i), p electrode 11 and n electrode 12 in contact with an exposed surface of p+ layer 5 and an exposed surface of n+ layer 6, respectively, are formed. They are formed, for example, by applying a silver paste along a surface of the contact holes described above by screen printing, and thereafter performing firing. By the firing, p electrode 11 and n electrode 12 made of silver in contact with silicon substrate 1 are formed. With this step, the solar cell of the present invention is completed.

Although the description has been given in the present embodiment using n-type silicon substrate 1, silicon substrate 1 may be of p-type. If semiconductor substrate 1 is of n-type, a pn junction is formed on the back surface of silicon substrate 1, with p+ layer 5 on the back surface of silicon substrate 1 and silicon substrate 1. If silicon substrate 1 is of p-type, a pn junction is formed on the back surface of silicon substrate 1, with n+ layer 6 on the back surface of silicon substrate 1 and p-type silicon substrate 1. Further, as silicon substrate 1, for example, polycrystalline silicon, monocrystalline silicon, or the like can be used.

### EXAMPLES

Hereinafter, examples will be described with reference to FIGS. 5(a) to 5(i) and S1 to S7 and S9 to S10 described above.

### Example 1

<<S1: FIG. 5(a)>>

Firstly, n-type silicon substrate 1 with slice damage caused during slicing removed was prepared. The removal of slice damage from silicon substrate 1 was performed by etching the surface of silicon substrate 1 using sodium hydroxide. As silicon substrate 1, a rectangular silicon substrate with a thickness of 200 μm and a side length of 125 mm was used.

<<S2: FIG. 5(b)>>

Next, texture mask 7 made of a silicon oxide film was formed on the back surface of silicon substrate 1 by the atmospheric pressure CVD method, and then texture structure 4 was formed on the light-receiving surface of silicon substrate 1. On this occasion, texture mask 7 had a thickness of 800 nm. Texture structure 4 on the light-receiving surface was formed by etching silicon substrate 1 having texture mask 7 formed thereon, using an etching solution. As the etching solution, a solution prepared by adding isopropyl alcohol to potassium hydroxide and heating the mixture to 80° C. was used. After texture structure 4 was formed, texture mask 7 on the back surface of silicon substrate 1 was removed using an aqueous solution of hydrogen fluoride.

<<S3: FIG. 5(c)>>

Next, diffision masks 8 made of a silicon oxide film were formed on the light-receiving surface and the back surface of silicon substrate 1, and an opening was formed in diffusion mask 8 on the back surface. Firstly, diffusion mask 8 made of a silicon oxide film was formed on each of the light-receiving surface and the back surface of silicon substrate 1, by the atmospheric pressure CVD method. On this occasion, diffusion mask 8 had a thickness of 250 nm. Then, an etching paste was applied by the screen printing method on diffusion mask 8 on the back surface of silicon substrate 1, at a desired portion where an opening was to be formed in diffision mask 8. As the etching paste, a paste containing phosphoric acid as an etching component, containing water, an organic solvent, and a thickener as components other than the etching component, and adjusted to have a viscosity suitable for screen printing was used. Subsequently, silicon substrate 1 was heat treated at 350° C., using a hot plate. Then, the silicon substrate was cleaned using a cleaning agent containing a surface active agent to remove the remaining etching paste, and thereby an opening was formed in diffusion mask 8. On this occasion, the opening was formed at a portion corresponding to a place where p+ layer 5 described below was to be formed.

<<S4: FIG. 5(d)>>

After p-type impurities were diffised, diffision masks 8 formed in S3 were cleaned using an aqueous solution of hydrogen fluoride (HF), to form p+ layer 5 as a conductive impurities diffused layer. Firstly, p-type impurities as conductive impurities were diffused into an exposed back surface of silicon substrate 1, by applying a solvent containing boron and then performing heating, After the diffusion, diffusion masks 8 described above on the light-receiving surface and the back surface of silicon substrate 1, and BSG (Boron Silicate Glass) formed by diffusing boron were all removed using an aqueous solution of hydrogen fluoride.

<<S5: FIG. 5(e)>>

Diffusion masks 8 were formed on the light-receiving surface and the back surface of silicon substrate 1, and an opening was formed in diffusion mask 8 on the back surface, Although the operation was performed as in S3, the opening in diffusion mask 8 was formed in S5 at a portion corresponding to a place where n+ layer 6 described below was to be formed.

<<S6: FIG. 5(f)>>

After n-type impurities were diffused, diffusion masks 8 formed in S5 were cleaned using an aqueous solution of hydrogen fluoride or the like, to form n+ layer 6 as a conductive impurities diff-used layer. Firstly, n-type impurities as conductive impurities were diffused into an exposed back surface of silicon substrate 1, for example by vapor-phase diffusion using POCl₃. After the diffusion, diffusion masks 8 described above on the light-receiving surface and the back surface of silicon substrate 1, and PSG (Phosphorus Silicate Glass) formed by diff-using phosphorus were all removed using an aqueous solution of hydrogen fluoride.

<<S7: FIG. 5(g)>>

As shown in FIG. 5(g), antireflection film 2 made of a silicon nitride film was formed on the light-receiving surface of silicon substrate 1, and passivation film 3 made of a silicon nitride film was formed on the back surface thereof.

In the present example, passivation film 3 formed of the first passivation film was employed, and passivation film 3 was formed by the plasma CVD method. The plasma CVD method was performed using a mixed gas containing 1360 sccm of nitrogen, 600 sccm of silane gas as a first gas, and 135 sccm of ammonia as a second gas, at a processing temperature of 450° C. The first passivation film made of a silicon nitride film had a refractive index of 3.2. Then, antireflection film 2 made of a silicon nitride film with a refractive index of 2.1 was formed on the light-receiving surface of silicon substrate 1.

<<S9: FIG. 5(h)>>

As shown in FIG. 5(h), to partially expose p+ layer 5 and n+ layer 6, passivation film 3 on the back surface of silicon substrate 1 was partially removed by etching, and contact holes were formed. The contact holes were formed as in S3, using the same etching paste as the one used in S3.

<<S10; FIG. 5(i)>>

As shown in FIG. 5(i), p electrode 11 and n electrode 12 in contact with an exposed surface of p+ layer 5 and an exposed surface of n+ layer 6, respectively, were formed. P electrode 11 and n electrode 12 were formed by applying a silver paste along a surface of the contact holes described above by screen printing, and thereafter performing firing at 650° C. By the firing, p electrode 11 and n electrode 12 made of silver in ohmic contact with silicon substrate 1 were formed.

Table 1 shows a short circuit current Isc (A), an open voltage Voc (V), a Fill Factor (F.F), and a maximum output operation voltage Pm value of a solar cell fabricated by the operation described above,

### Example 2

A solar cell was fabricated by performing all the steps described in Example 1 except for S7.

In the present example, passivation film 3 formed of the first passivation film and the second passivation film made of a silicon oxide film X was employed in S7. Firstly, silicon substrate 1 was treated by the thermal oxidation method at 800° C. for 90 minutes, and thereby a silicon oxide film was formed on each of the light-receiving surface and the back surface of silicon substrate 1. Next, a silicon nitride film with a refractive index of 3.2 was formed by the plasma CVD under the same conditions as those of Example 1. The silicon oxide film on the light-receiving surface was removed by treatment with hydrogen fluoride (i.e., immersing the silicon oxide film in a 2.5% aqueous solution of hydrogen fluoride for 100 seconds). Then, antireflection film 2 made of a silicon nitride film with a refractive index of 2.1 was formed on the light-receiving surface of silicon substrate 1.

Table 1 shows a short circuit current Isc (A), an open voltage Voc (V), a Fill Factor (F.F), and a maximum output operation voltage Pm value of the solar cell fabricated by the operation described above.

### Comparative Example

A solar cell was fabricated by performing all the steps described in Example 1 except for S7. Passivation film 3 formed of a silicon oxide film only was employed. Firstly, silicon substrate 1 was treated by the thermal oxidation method at 800° C. for 90 minutes, and thereby a silicon oxide film was formed on each of the light-receiving surface and the back surface of silicon substrate 1. On the silicon oxide film, an about 2000 angstrom-thick silicon oxide film formed by the atmospheric pressure CVD method was further deposited. The silicon oxide film on the light-receiving surface was removed by treatment with hydrogen fluoride (i.e., immersing the silicon oxide film in a 2.5% aqueous solution of hydrogen fluoride for 100 seconds). Then, antireflection film 2 made of a silicon nitride film with a refractive index of 2.1 was formed on the light-receiving surface of silicon substrate 1.

Table 1 shows a short circuit current Isc (A), an open voltage Voc (V), a Fill Factor (F.F), and a maximum output operation voltage Pm value of the solar cell fabricated by the operation described above.

TABLE 1

| | Isc (A) | Voc (V) | F.F. | Pm |
|---|---|---|---|---|
| Example 1 | 4.159 | 0.627 | 0.761 | 1.987 |
| Example 2 | 4.183 | 0.636 | 0.760 | 2.022 |
| Comparative | 4.091 | 0.635 | 0.763 | 1.982 |
| Example | | | | |

### <Examination of Results of Properties>

Table 1 shows results of the properties of the respective solar cells. The open voltage in Example 1 is slightly lower than that of the comparative example. However, since the short circuit current in Example 1 is increased more than that of the comparative example, it has been shown as a result of a comprehensive evaluation that the properties of the solar cell of Example 1 are improved when compared with those of the comparative example. Further, it has been shown that the properties of the solar cell of Example 2 are significantly improved when compared with those of Comparative Examples 1 and 2.

It should be understood that the embodiment and examples disclosed herein are illustrative and non-restrictive in every respect. The scope of the present invention is defined by the scope of the claims, rather than the description above, and is intended to include any modifications within the scope and meaning equivalent to the scope of the claims.

1. A solar cell including a first passivation film made of a silicon nitride film formed on a surface opposite to a light-receiving surface of a silicon substrate, said first passivation film having a refractive index of not less than 2.6.

2. The solar cell according to claim 1, wherein the solar cell is a back surface junction solar cell having a pn junction formed on said surface opposite to said light-receiving surface of said silicon substrate.

3. The solar cell according to claim 1, wherein a second passivation film including a silicon oxide film and/or an aluminum oxide film is formed between said silicon substrate and said first passivation film.

4. A method of manufacturing a solar cell including a first passivation film made of a silicon nitride film formed on a surface opposite to a light-receiving surface of a silicon substrate, said first passivation film having a refractive index of not less than 2.6,
said method comprising the step of forming said first passivation film by a plasma CVD method using a mixed gas containing a first gas and a second gas,
a mixing ratio of said second gas to said first gas in said mixed gas being not more than 1.4, said mixed gas containing nitrogen, said first gas including silane gas, and said second gas including ammonia gas.

5. The method of manufacturing a solar cell according to claim 4, comprising the step of forming a pn junction on said surface opposite to said light-receiving surface of said silicon substrate.

6. The method of manufacturing a solar cell according to claim 4, comprising the step of forming a second passivation film including a silicon oxide film between said silicon substrate and said first passivation film,
wherein the silicon oxide film is formed by a thermal oxidation method.
